(19) United States
(12) Patent Application Publication
(10) Pub. No.: US 2015/0221800 A1
(43) Pub. Date: Aug. 6, 2015

(54) SPECTRAL LIGHT SPLITTING MODULE AND PHOTOVOLTAIC SYSTEM INCLUDING CONCENTRATOR OPTICS

(71) Applicants: DOW GLOBAL TECHNOLOGIES LLC, Midland, MI (US); CALIFORNIA INSTITUTE OF TECHNOLOGY, Pasadena, CA (US)

(72) Inventors: Carissa N. Eisler, Santa Clarita, CA (US); Emily D. Kosten, Pasadena, CA (US); Harry A. Atwater, Pasadena, CA (US); Emily C. Warmann, Riverside, CA (US); Carrie E. Hofmann, Altadena, CA (US); Rebekah K. Feist, Midland, MI (US); James C. Stevens, Richmond, TX (US); Weijun Zhou, Sugar Land, TX (US); Michael E. Mills, Midland, MI (US); Narayan Ramesh, Midland, MI (US)

(21) Appl. No.: 14/424,291

(22) PCT Filed: Aug. 30, 2013
(86) PCT No.: PCT/US2013/057557

§ 371 Date: Feb. 26, 2015

Related U.S. Application Data
(60) Provisional application No. 61/695,216, filed on Aug. 30, 2012.
(60) Provisional application No. 61/740,969, filed on Dec. 21, 2012.

(51) Int. Cl. H01L 31/054; H02S 40/22

(52) U.S. Cl. CPC H01L 31/0549; H02S 40/22

(57) ABSTRACT

A light splitting optical module that converts incident light into electrical energy, the module including a solid optical element comprising an input end for receiving light, a first side, and a second side spaced from the first side, a first solar cell adjacent to the first side of the solid optical element, and a second solar cell adjacent to the second side of the solid optical element. The first solar cell is positioned to absorb a first subset of incident light and reflect a first remainder of the incident light to the second solar cell through the solid optical element.

### PRIORITY

The present patent application claims priority from U.S. Provisional patent application having Ser. No. 61/695,216, filed on Aug. 30, 2012, entitled OPTICS FOR FULL SPECTRUM, ULTRAHIGH EFFICIENCY SOLAR ENERGY CONVERSION, and U.S. Provisional patent application having Ser. No. 61/740,969, filed on Dec. 21, 2012, entitled SPECTRAL LIGHT SPLITTING MODULE AND PHOTOVOLTAIC SYSTEM INCLUDING CONCENTRATOR OPTICS, wherein the entirety of said provisional patent applications is incorporated herein by reference.

### TECHNICAL FIELD

The present invention relates to photovoltaic devices that convert incident light into electrical energy. More specifically, the present invention relates to photovoltaic devices including a solid optical element with a plurality of photovoltaic cells configured in a parallelepiped arrangement.

### BACKGROUND

Photovoltaic cells, which may also be referred to as solar cells or PV cells, are useful for converting incident light, such as sunlight, into electrical energy. These cells can be provided as single junction solar cells, which have one specifically defined band gap that has an inherently low conversion efficiency. This is because a single photovoltaic cell is photovoltaically responsive only to a small portion of the broadband spectrum of the incident light and therefore converts only a small portion of incident light into energy. A number of ways of increasing the efficiency of solar cells have therefore been used and proposed.

One common method used for achieving higher photovoltaic efficiencies is to use multiple band gaps together to form a multi-junction solar cell. Such multi-junction solar cells are made of a system of different semiconductor materials that have different band gap energies that correspond with different parts of the solar spectrum. Only photons having an energy that matches or is slightly larger than the energy gap are used most efficiently. Thus, having a wider range of band gaps allows the system to convert more of the spectrum in a relatively efficient manner. Photons whose energy is lower than the gap are not absorbed and subsequently converted, and in some cases can be parasitically absorbed and converted to wasted heat. Photons with energy greater than the band gap convert only part of their energy matching the energy gap into electrical energy while the excess energy is lost mainly as wasted heat.

Conventionally, multi-junction cells are grown as monolithic sticks such that every semiconductor acts as a filter that absorbs light above its band gap and below the band gap of the cell above it. Although traditional multi-junction tandem solar cells provide advantages over single junction solar cells, further efficiencies can be achieved through the use of light splitting optics that are used to split the incident solar radiation into multiple spectral bands and to direct those spectral bands towards different and corresponding solar cells. In this way, subcells can be grown and electrically connected independently, avoiding the problems of lattice and current matching. Each targeted cell is designed to have a band gap tailored to the spectral band directed to it in order to help maximize energy conversion. That is, the splitting optics partition the incident light into segments or slices and then direct the slices independently to photovoltaic cells with appropriate band gaps.

Photovoltaic systems that utilize light splitting or spectrum splitting for improving solar conversion efficiency have been described in the patent and technical literature. Examples include U.S. Pat. Publication. Nos. 2009/0056788 (Gibson) and 2011/0284054 (Wanlass); Barnett et al., Progress in Photovoltaics: Research and Applications, “Very High Efficiency Solar Cell Modules,” 17:75-83 (2009); Imenes et al., Solar Energy Materials and Solar Cells, “Spectral Beam Splitting Technology for Increased Conversion Efficiency in Solar Concentrating Systems, A Review,” 84:19-69 (2004); McCambridge et al, Progress in Photovoltaics: Research and Applications, “Compact Spectrum Splitting Photovoltaic Module With High Efficiency,” 19:352-360 (2011); Mitchell et al., Progress in Photovoltaics: Research and Applications, “Four-junction Spectral Beam-Splitting Photovoltaic Receiver With High Optical Efficiency,” 19:61-72 (2011); and Peters et al., Energies, “Spectrally-Selective Photonic Structures for PV Applications,” 3:171-193 (2010).

While photovoltaic systems using light splitting technology with solar cells should theoretically generally improve the efficiencies of converting incident light into electrical energy, there is a need to provide systems that can realistically allow for even higher efficiencies with better light splitting optical structures.

### SUMMARY

The present invention is directed to a photovoltaic system for converting incident light into electrical energy that may be referred to as a polyhedral specular reflector. The systems can be used to divide light to a series of single junction solar subcells or a series of tandem grown subcells. The systems can generally include an array of to solar cells or photovoltaic cells arranged on opposite sides of a solid optical element, which can be used in combination with concentrating optics. The relatively high efficiency of these systems is the result of positioning each subcell so that it can absorb a specific subset of the light spectrum that is most efficiently absorbed by that cell, and then reflecting the remaining light through the solid optical element onto a subsequent cell that can then absorb its own subset of the light spectrum. This process of absorbing and reflecting light at each solar cell continues, with decreasing amounts of light being available for absorption and reflection at each subsequent solar cell, until an optional back reflector is reached, which is generally at an opposite end of the array of cells from the input end. The solar cells are positioned so that the first cell reached by the incident light is capable of absorbing the highest energy of the spectrum, while the last cell reached is capable of absorbing the lowest energy of the spectrum. In an embodiment of the invention, at least two photovoltaic cells are used in combination with an optical concentrating element, wherein the cells are configured as a solid parallelepiped that aids in optical coupling of incident light.

In one aspect of the invention, a light splitting optical module is provided that converts incident light into electrical energy. The module includes a solid optical element comprising an input end for receiving light, a first side, and a second side spaced from the first side, a first solar cell adjacent to the first side of the solid optical element, and a second solar cell adjacent to the second side of the solid optical element. The first solar cell is positioned to absorb a first subset of incident light and reflect a first remainder of the incident light to the second solar cell through the solid optical element.

In another aspect of the invention, the light splitting optical module is combined with an optical concentrator element that collects and concentrates incident light, wherein the optical concentrator element is in optical contact with the input end of the solid optical element.

### BRIEF DESCRIPTION OF THE DRAWINGS

The present invention will be further explained with reference to the appended Figures, wherein like structure is referred to by like numerals throughout the several views, and wherein:

FIG. 1 is a perspective view of a photovoltaic system of the invention;

FIG. 2 is an enlarged side schematic view of the parallelepiped arrangement of solar cells shown in FIG. 1;

FIG. 3 is a top view of plural photovoltaic systems of the type illustrated in FIG. 1 arranged into a module;

FIG. 4 is a perspective view of a portion of the module illustrated in FIG. 3;

FIG. 5 is a graph expressing exemplary impact of concentration on optical losses using a photovoltaic system of the invention;

FIG. 6 is a side view of a parallelepiped arrangement with individual cell concentrators along with a trough concentrator in accordance with the invention; and

FIG. 7 is a side view of a parallelepiped arrangement similar to that of FIG. 6, but without a separate trough concentrator.

### DETAILED DESCRIPTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited throughout this specification are incorporated herein by reference in their respective entireties for all purposes.

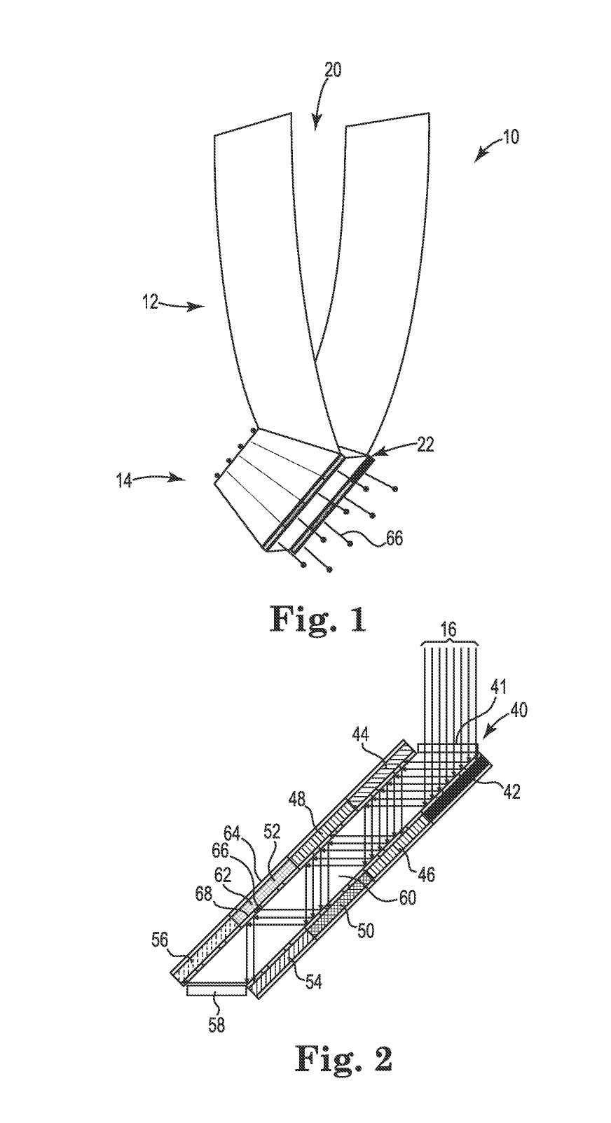

Referring now to the figures, and initially to FIGS. 1 and 2, an exemplary embodiment of a photovoltaic system 10 is illustrated, which generally includes an optical concentrator 12 and a light splitting optical module 14. System 10 can be used for photovoltaic conversion of incident light 16 into electrical energy, as will be described in further detail below. The system 10 may also be referred to as a polyhedral spectral reflector.

Optical concentrator 12 is illustrated as a trough concentrator or a compound parabolic concentrator that includes an input end 20, an output end 22 spaced from the input end, and a concentrator region 24 extending between the input and output ends 20, 22. The optical concentrator 12 of this illustrated embodiment can be considered to be compound parabolic, although the relative shape and size shown are intended to be representative in that the concentrator can include a number of different curvilinear shapes such as a parabolic, flat-sided light funnel, for example. Shapes other than compound parabolic are often not as optically efficient, but are considered to be within the scope of the invention. The shapes and sizes of the elements of the trough concentrator are designed and chosen to optimize the concentration of light that enters the system. The inner area of the concentrator region 24 can be empty or can be at least partially filled. The input end 20 can optionally include a cover, or it can be open as illustrated in FIG. 1. The concentrator may be one-dimensional or two-dimensional, wherein a two-dimensional embodiment will often require more tracking, but can give higher concentration.

Optical concentrator 12 may be provided to have a predetermined concentrating power over a wide range. For example, the concentrating power of concentrator 12 may range from 10× to 20× for a one-dimensional concentrator, for example, but can be much higher for a two-dimensional concentrator (e.g., 100× to 400×). Relatively low to moderate levels of concentration can allow the concentrator 12 to be compact while minimizing the heat load and cost of components. It is also desirable to minimize the spread of angles from the concentrator to ensure the highest light splitting efficiency. Therefore, the desire for concentration can be balanced with the desire for light rays to enter the optical module 14 normal to the plane at the top of the module. In addition, with the trough concentrator embodiment, solar tracking may be provided in only a single dimension.

In one embodiment, optical concentrator 12 has a concentrating power of 7×, and an acceptance angle of +/−2 degrees from the normal direction. Although the actual measurements may vary widely, one exemplary optical concentrator 12 can have a height of approximately 8 cm, a width at its input end 20 of approximately 14 mm, and a width at its output end of approximately 2 mm.

The light splitting optical module 14 is located below the output end 22 of the concentrator 12 such that the light from output end 22 is directed into the input area 40 of the optical module 14. This area 40 can optionally include an anti-reflective coating or material 41 positioned on the top of the parallelepiped at its input area 40 into which the incident light 16 enters. The antireflective coating 41 helps to enable the largest possible amount of incident light to enter the optical module 14.

In an embodiment of the invention, a cell can be positioned at the end where the light enters the parallelepiped (i.e., where the coating 41 is illustrated), which cell can be configured to act as a power generator for the highest energy light, in order to more optimally convert its power. Therefore, this cell can enable the use of very high index core material in the parallelepiped that will improve performance. Most high index materials usually absorb the very highest energy light in the solar spectrum. Without a subcell on top of the structure, this high energy light would be parasitically absorbed in the parallelepiped material before it can be converted into power. Alternatively, lower index core materials can be chosen since these usually do not absorb the highest energy light. It is noted that the incident light 16 described and illustrated herein will typically be white light that exits from the concentrator 12. For illustrative purposes, this incident light 16 is split into eight different spectral bands, which are schematically illustrated with eight different colors in the figures, wherein these spectral bands will be processed by solar cells of the system described below. However, a different number of cells can instead be used in the parallelepiped structure, and in such a case, a representative illustration would split the light into a corresponding number of spectral bands.

The optical module 14 includes two or more photovoltaic cells that are independently tuned to photovoltaically absorb and convert a predefined subset of the light spectrum to electrical power and to reflect the remainder of the light to which it is subjected. That is, light that is not absorbed by a cell will travel to the next cell in the series. To minimize losses from this traveling process, filters can be used to reflect light that cannot be converted in the cell and prevent it from traveling through the cell. Generally, at least a first photovoltaic cell photovoltaically responds most efficiently to a first spectral bandwidth portion of the incident light and the second photovoltaic cell photovoltaically responds most efficiently to a second spectral bandwidth portion of the incident light, etc., wherein the bands are arranged in order of the highest energy to the lowest energy. For purposes of illustration, optical module 12 includes eight differently tuned photovoltaic cells, including first cell 42, second cell 44, third cell 46, fourth cell 48, fifth cell 50, sixth cell 52, seventh cell 54, and eighth cell 56, although it is understood that a different number of photovoltaic cells may be used. Each of the eight photovoltaic cells may be either a single or multiple junction photovoltaic cell.

As shown, the photovoltaic cells of the optical module 12 are arranged so that four of the cells are positioned adjacent to each other in a row along one side of a parallelepiped support structure 60, and so that the remaining four cells are positioned adjacent to each other in a row along an opposite side of the support structure 56. The rows are generally arranged to be at an angle to the input area 40 of the optical module 12, such as at an approximately 45-degree angle. The illustrated light entry angle (i.e., normal incidence) will be typical for light that has not passed through a concentrator, in that when a concentrator is used, at least some of the light will enter at an angle that is not normal to the plane at which the light enters the system. In this way, when incident light 16 enters the input area 40 of the optical module 12, it will be directed at a 45 degree to a surface of the first cell 42 that is facing toward the support structure 56, and light that is reflected from this surface will be directed toward the second cell 44 at the same angle (i.e., approximately 45 degrees). That is, when the cells are arranged in this manner, reflected light will move through the support structure 60 at an angle that is generally perpendicular to the angle at which it contacted the previous photovoltaic cell.

It is further understood that the photovoltaic cells are generally parallel to each other across the support structure 60, although they can be angled at least slightly relative to each other (e.g., angled at a 1-2 degree angle relative to each other, or angled at an angle of less than 1 degree or greater than 2 degrees). In such an embodiment, if the light enters very near normal incidence, the absorption and reflection of the various subsets of the light spectrum will be at least slightly less efficient than in an optical module where the cells are parallel to each other, since the path that reflected light takes will be slightly different when the cells are parallel than when they are not parallel. That is, the structures shown and described herein are generally directed to a parallelepiped, but other geometries are also contemplated that can provide for similar movement of light along a structure.

The support structure 60 of an embodiment of the invention can be made of a solid material, such as glass, plastic, or GaP, for example, although other materials are contemplated. Generally, the material for the support structure 60 can be any material with a relatively high index of refraction that is transparent across most of the solar spectrum. Using a support structure with a relatively high index of refraction can advantageously provide for higher refraction of the incoming light, which will allow the structure to both incorporate higher concentration and also minimize the angular spread of the incoming light. This will help to minimize optical losses. The material of the support structure 60 can also be transparent and non-scattering to allow for smooth movement of light through the module 14.

The optical module 14 further optionally includes a back reflector 58 to reflect any unabsorbed light back through the structure for possible conversion. The reflector 58 is generally parallel to input area 40 of the light splitting module 14, but can be at least slightly angled relative to it. In such an arrangement, the back reflector 58 will also be arranged at an approximate 45-degree angle to the photovoltaic cells that are adjacent to it (e.g., photovoltaic cells 54, 56 of this figure). The back reflector 58 can be planar in order to direct light through the structure in reverse from its original path, or can be textured or otherwise configured to randomize the path of the light back through the structure. The back reflector 58 can optionally be replaced with a photovoltaic cell that absorbs the lowest energy light, and can further include a filter.

Each of the photovoltaic cells of the module 14 can include a number of features, such as a central cell active region 62 (shown relative to solar cell 52, although the description can apply to all of the cells in the structure), a back contact and reflector 64, one or more contact grid areas 66, and a layer 68 that can include an antireflective coating/filter and adhesive. Each of the photovoltaic cells is generally tuned or has band gap characteristics that allow it to absorb a certain spectral bandwidth portion of the incident light to which it is subjected, and then includes a reflector that allows it to reflect the portion that is not absorbed on the first path. The cells can also have additional optics (e.g., plasmonic structures) to improve the light trapping capabilities of the system. Each of the photovoltaic cells of the exemplary embodiment of system 10 is described generally below, although it is understood that the wavelengths and colors of this embodiment represent only one of many ways that the incident light can be split. The colors of the light rays are only for illustrative purposes; however, each spectral light band consists of lower energy photons than the band above it, which is why the cells are transparent to non-absorbed light. The bandgaps described herein may be adjusted to accommodate the number of cells of the particular parallelepiped. In addition, it may be possible to split the system into two sets of cells, which will allow for the addition of another light splitting element to the design (e.g., dichroic splitter).

The filters can be provided in a number of ways. For one example, a nanoimprinting process can be used to pattern an optical filter for each cell onto the parallelepiped, rather than on the cell. For another example, the filter can be molded. Further, with any of the structures used, flexible circuitry can be used to ease assembly, wherein the cells can be assembled onto a sheet that can be formed to fit the parallelepiped or other geometry.

The subcells used with the systems of the invention are electrically independent, and may include an insulating material (e.g., an insulating polymer) between them, due to the proximity of cells to one another. It is further contemplated that the structure of the optical module can allow for photon recycling between cells, since they are optically active with each other.

As is described and illustrated herein, the subcells can either be used to split the light themselves (i.e., to absorb only what is above their bandgap and reflect everything else with their back reflectors), or put the filters on the front of the subcells to help in case there are parasitic losses. For example, if a cell that is designed to absorb purple light parasitically absorbs some red light, then when a red photon hits it, it could be absorbed and therefore lost at that reflector. Having a filter helps to mitigate the losses because only the purple photons are let through and the red photons are blocked from entering. In a configuration wherein each cell has its own concentrator (discussed below), filters are used so that the concentrators do not send light out of the structure instead of allowing it to continue down the structure until it reaches the correct subcell.

First photovoltaic cell 42 is tuned (e.g., it has band gap characteristics) to absorb the spectral bandwidth portion of incident light including wavelengths from 280 nm to 470 nm, which is represented by the indigo light ray. The spectral bandwidth portion of the incident light that is outside of this wavelength range will ideally be reflected toward the photovoltaic cell 44, as is shown in FIG. 2.

Second photovoltaic cell 44 is tuned (e.g., it has band gap characteristics) to absorb the spectral bandwidth portion of incident light including wavelengths from 470 nm to 561 nm, which is represented by the blue light ray. The spectral bandwidth portion of the incident light that is outside of this wavelength range will ideally be reflected toward the photovoltaic cell 46.

Third photovoltaic cell 46 is tuned (e.g., it has band gap characteristics) to absorb the spectral bandwidth portion of incident light including wavelengths from 561 nm to 663 nm, which is represented by the blue-green light ray. The spectral bandwidth portion of the incident light that is outside of this wavelength range will ideally be reflected toward the photovoltaic cell 48.

Fourth photovoltaic cell 48 is tuned (e.g., it has band gap characteristics) to absorb the spectral bandwidth portion of incident light including wavelengths from 663 nm to 761 nm, which is represented by the green-yellow light ray. The spectral bandwidth portion of the incident light that is outside of this wavelength range will be reflected toward the photovoltaic cell 50.

Fifth photovoltaic cell 50 is tuned (e.g., it has band gap characteristics) to absorb the spectral bandwidth portion of incident light including wavelengths from 761 nm to 899 nm, which is represented by the yellow light ray. The spectral bandwidth portion of the incident light that is outside of this wavelength range will ideally be reflected toward the photovoltaic cell 52.

Sixth photovoltaic cell 52 is tuned (e.g., it has band gap characteristics) to absorb the spectral bandwidth portion of incident light including wavelengths from 899 nm to 1078 nm, which is represented by the yellow-orange light ray. The spectral bandwidth portion of the incident light that is outside of this wavelength range will ideally be reflected toward the photovoltaic cell 54.

Seventh photovoltaic cell 54 is tuned (e.g., it has band gap characteristics) to absorb the spectral bandwidth portion of incident light including wavelengths from 1078 nm to 1319 nm, which is represented by the orange-red light ray. The spectral bandwidth portion of the incident light that is outside of this wavelength range will ideally be reflected toward the photovoltaic cell 56.

Eighth photovoltaic cell 56 is tuned (e.g., it has band gap with wavelengths from 1319 nm to 1797 nm, which is represented by the red or deep red light ray. If there is any portion of the spectral bandwidth of the incident light that remains after absorption by the cell 56, this portion of the light will ideally be directed to the optional back reflector or solar cell 58. In a system where all of the incident light enters the parallelepiped normally, all or most of the light with photons of a high enough energy will be absorbed by the time it reaches this reflector 58. However, with concentration and non-idealities in the system, some of the light will not have been directed to a cell that could absorb it. This will be the portion of the light that will reach the reflector and be reflected back up into the parallelepiped, where it can be reflected through the cells in reverse order (i.e., lowest band gap to highest band gap) until it is either absorbed by one of the cells or escapes from the system. In certain systems, therefore, little or no usable light will reach the reflector 58.

In operation, the eight photovoltaic cells 42, 44, 46, 48, 50, 52, 54, 56 are arranged such that the entering and reflecting light will be absorbed and reflected from the highest energy down to the lowest energy (i.e., ultraviolet light is absorbed first and infrared light is absorbed last). As is schematically illustrated in FIG. 2, with each sequential absorption and reflection of portions of the incident light, fewer spectral bandwidth portions will move to the next photovoltaic cell in the sequence. Thus, the last colors to be absorbed and/or reflected will travel the greatest distance through the optical module 14. The absorbed light from each of the photovoltaic cells is in operative communication with one or more electrical leads 66.

The following table shows exemplary band gaps for an eight cell parallelepiped design of an optical module, such as that described above, with example III-V materials and growth substrates (for lattice matching):

TABLE 1

| E_{g} (eV) | III-V Alloy | Substrate |
|---|---|---|
| 0.74 | In_{0.53}Ga_{0.47}As | InP |
| 0.94 | In_{0.71}Ga_{0.29}As_{0.62}P_{0.38} | InP |
| 1.15 | In_{0.87}Ga_{0.13}As_{0.28}P_{0.72} | InP |
| 1.42 | GaAs | GaAs |
| 1.58 | Al_{0.1}Ga_{0.9}As | GaAs |
| 1.84 | Ga_{0.51}In_{0.49}P | GaAs |
| 2.15 | Al_{0.20}Ga_{0.32}In_{0.48}P | GaAs |
| 2.61 | Ga_{0.85}In_{0.15}N | GaN |

These alloys are only intended to be exemplary and provide choices in the III-V family that can therefore provide for good absorption and performance due to their high quality growth/direct band gaps. In addition, these alloys can provide an ability to be grown lattice-matched (i.e., without defects on the growth substrate) for higher material quality. The materials can include tunable properties, specifically to a cell band gap within +/−0.1 eV of the desired state, such that even if the band gaps vary slightly, the efficiencies will remain similar.

The photovoltaic cells shown in the figures are illustrated as single junction cells; however, it is understood that the cells may instead be multi-junction cells. The cells may be thin-film or epitaxially lifted off cells, for example. Embodiments of the invention may also include the use of narrow filters and/or anti-reflective coating(s) in combination with the solar cells. If the anti-reflective materials are used, they may include 3-10 layers for example, and may include multiple refractive index materials.

In one exemplary embodiment, the overall height of a particular light splitting optical module 14 can be approximately 8 mm high, with the photovoltaic cells of the structure having a length of approximately 2.8 mm. Each of the photovoltaic cells of a particular optical module 14 can have the same physical dimensions, or at least one of the cells can have dimensions that are at least slightly different than the other cells of the structure. The cell size and area can be tuned to adjust the spectrum independently, such that the embodiments are very amenable to any series/parallel electrical configuration.

Although the optical module 14 is illustrated and described as having eight solar cells, more or less than eight of such solar cells can instead be provided for a particular optical module, wherein the particular subset of the light spectrum that each of the cells will absorb and reflect will then be different than that described above for an eight cell structure. In addition, the wavelength ranges associated with each of the eight solar cells described above can either be smaller or larger, depending on the particular materials used, the tuning of the system, the efficiency of the optical design for different wavelengths, etc.

The relatively high efficiencies that can be achieved by the photovoltaic systems of the invention occur for a number of reasons. That is, the higher index material can help to “straighten out” the entering light rays via light refraction, which will help to direct light along a desired path, thereby allowing for higher concentration. Higher concentration allows for higher subcell performance, therefore, it can be advantageous to couple concentration and a high index support structure to achieve the highest efficiencies. In addition, embodiments of the invention allow for the use of many cells, each of which can have a reflector that provides for better absorption and thinner cells to maximize the voltage available from a solar cell.

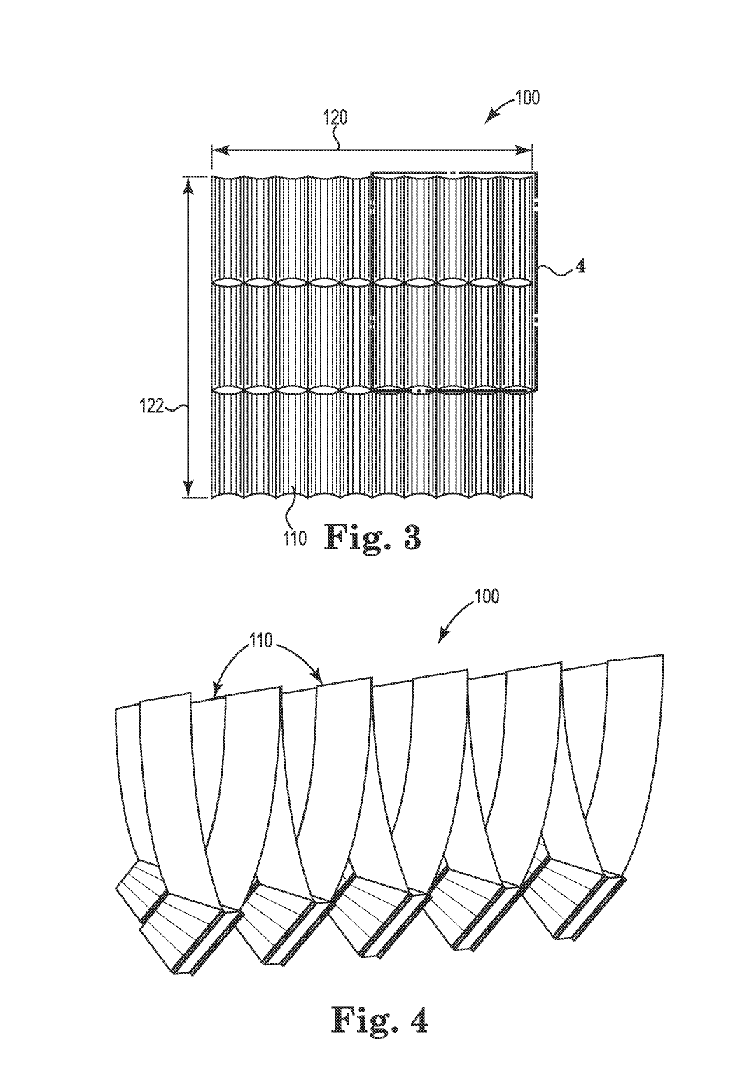

Referring additionally to FIGS. 3 and 4, a module 100 is illustrated that includes multiple photovoltaic systems 110 arranged in a grid-like pattern. Each of the photovoltaic systems can include its own optical concentrator (e.g., trough concentrator) and light splitting optical module, such as those described above relative to the photovoltaic systems 10. As shown in FIG. 3, the systems 110 are arranged in rows and columns in a relatively tightly packed manner, wherein one exemplary embodiment includes a width 120 of 14 cm and a depth 122 of 15 cm. However, the systems 110 can instead be spaced at least slightly from each other within a particular module 100. Modules of this type can advantageously expose a relatively large number of optical concentrators to incident light over a predetermined area. One or multiple modules can in turn be mounted to a common framework, wherein the entire framework and/or individual modules can include tracking or non-tracking features. In one embodiment, the modules are arranged to allow for fluid and/or air to flow between the parallelepipeds to cool the backsides of the cells. In embodiments of the invention, single-axis tracking can be used and in other embodiments, different levels of concentration and tracking can be used, such as low-level concentration (e.g., 5× to 6×), or high levels of concentration (e.g., 100× or greater) that can also utilize dual-axis tracking.

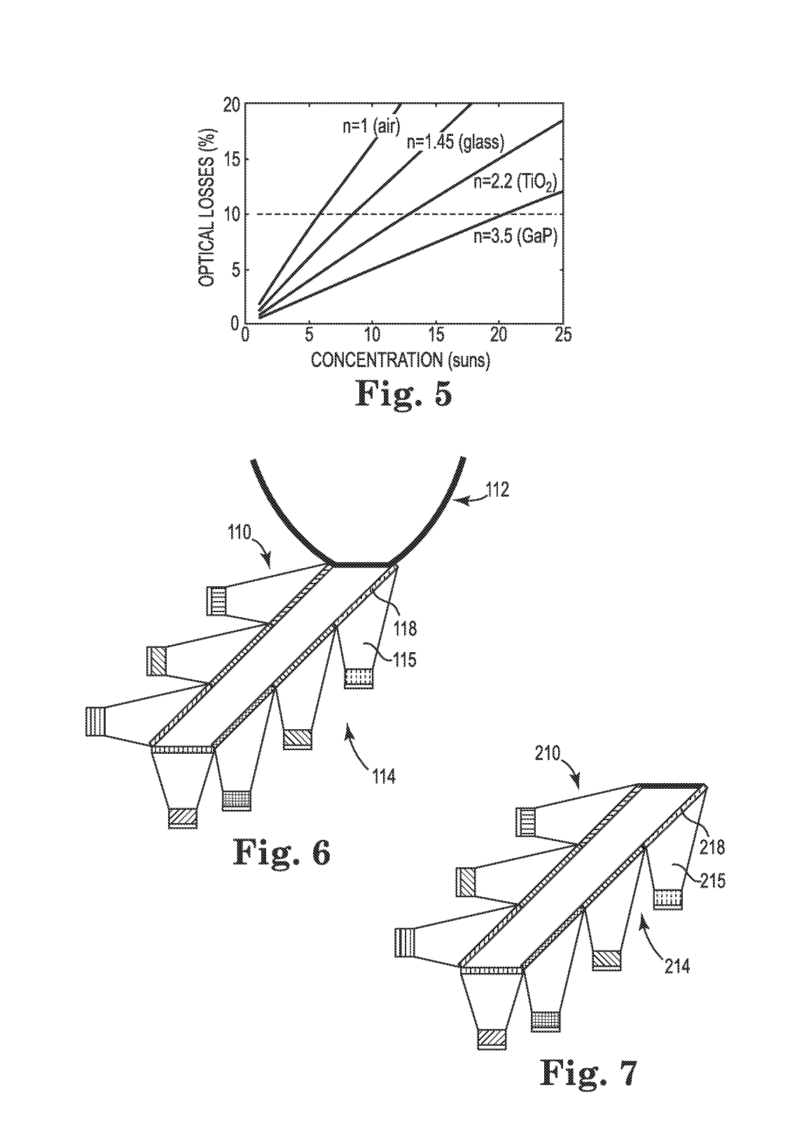

FIG. 5 is a graph expressing the exemplary impact of concentration on optical losses using a photovoltaic system of the invention. In particular, this graph illustrates the percentage of optical losses for increasing levels of concentration from a one-dimensional compound parabolic concentrator for materials having different indices of refraction. As shown, to minimize optical losses as the concentration increases, the importance of a higher index slab also increases (e.g., an index greater than that of air). This is due to the fact that higher concentrations cause the incident light to depart further from a normal entry angle that allows for a light path similar to that shown in FIG. 2 (e.g., hitting the first solar cell at a 45 degree angle). A higher index slab and/or concentrator with a limited output angle range can minimize this issue. In addition, although higher concentration is desired for better subcell performance, the optical losses are preferably minimized in order for the light splitting to function effectively.

FIG. 6 illustrates another photovoltaic system 110 in accordance with the invention, which generally includes an optical concentrator 112, a light splitting optical module 114, and a series of secondary concentrators 115. As is discussed above relative to system 10, the module 114 includes two or more photovoltaic cells 118 arranged generally into a parallelepiped structure, wherein FIG. 6 provides an exemplary embodiment with seven of such cells 118, each of which includes one or more filters. Six of such cells are on the sides of the parallelepiped and one cell is on the bottom. With this embodiment, additional or secondary concentrators 115 are provided to concentrate light from each filter or cell 118, thereby providing a light path that includes primary concentration, light splitting, and then secondary concentration.

FIG. 7 illustrates another photovoltaic system 210 in accordance with the invention, which generally includes a light splitting optical module 214 and a series of concentrators 215. As is discussed above relative to system 110, the module 214 includes two or more photovoltaic cells 218, wherein FIG. 7 provides an exemplary embodiment with seven of such cells 218, each of which includes one or more filters. With this embodiment, concentrators 215 are provided to concentrate light from each filter or cell 218, thereby providing a light path that includes light splitting, and then concentration, without a primary or initial concentrating of the light.

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

1. A light splitting optical module that converts incident light into electrical energy, the module comprising:
a solid optical element comprising an input end for receiving light, a first side, and a second side spaced from the first side;
a first solar cell adjacent to the first side of the solid optical element; and
a second solar cell adjacent to the second side of the solid optical element;
wherein the module is configured to provide absorbance of incident light above at least one of the cells with either:
the first solar cell that is positioned to absorb a first subset of incident light and reflect a first remainder of the incident light to the second solar cell through the solid optical element, wherein the first solar cell has a higher band gap than the second solar cell; or
a first filter that is adjacent to the first side of the solid optical element and a second filter that is adjacent to the second side of the solid optical element, wherein the first filter transmits a first subset of incident light and reflects a first remainder of the incident light to the second filter through the solid optical element.

2. The optical module of claim 1 in combination with an optical concentrator element that collects and concentrates incident light, wherein the optical concentrator element directs light into the input end of the solid optical element.

3. The optical module of claim 1, further comprising:
a first pair of solar cells comprising the first solar cell and the second solar cell spaced from each other across a width of the solid optical element; and
a second pair of solar cells comprising a third solar cell and a fourth solar cell spaced from each other across the width of the solid optical element, wherein the first pair of solar cells is adjacent to the second pair of solar cells;
wherein the first and second pairs of solar cells comprise a portion of a parallelepiped structure.

4. The optical module of claim 1, further comprising the first and second solar cells and at least two additional solar cells arranged in a series so that a subset of light is sequentially absorbed by each solar cell and a remainder of the light is reflected, with decreasing amounts of light being available for absorption and reflection at each subsequent solar cell.

5. The optical module of claim 1, further comprising a back reflector at an opposite end of the solid optical element from the input end.

6. The optical module of claim 1, further comprising a solar cell at an opposite end of the solid optical element from the input end.

7. The optical module of claim 1, wherein each of the first and second solar cells comprises an active cell region, an antireflective surface adjacent to a first side of the active cell region, and a reflector surface adjacent to a second side of the active cell region.

8. The optical module of claim 1, wherein each of the first and second solar cells is electrically independent.

9. The optical module of claim 3, wherein the solar cells of each of the first and second pairs of solar cells are parallel to each other and are arranged at an approximately 45 degree angle relative to the input end of the solid optical element.

10. The optical module of claim 1, wherein the first solar cell is in optical contact with the first filter, and the second solar cell is in optical contact with the second filter.

11. The optical module of claim 10, further comprising a first optical concentrator element positioned between the first filter and the first solar cell.

12. The optical module of claim 10, in combination with a second optical concentrator element that collects and concentrates incident light, wherein the optical concentrator element directs light into the input end of the solid optical element.

13. The optical module of claim 11, in combination with a second optical concentrator element that collects and concentrates incident light, wherein the optical concentrator element directs light into the input end of the solid optical element.

14. A photovoltaic system that converts incident light into electrical energy, the system comprising:
an optical concentrator element for collecting and concentrating incoming incident light, the concentrator element comprising an input end, and an output end, and
a light splitting optical module comprising:
a solid optical element comprising an input end in optical communication with the output end of the optical concentrator element, a first side, and a second side spaced from the first side;
a first solar cell adjacent to the first side of the solid optical element; and
a second solar cell adjacent to the second side of the solid optical element;
wherein the first solar cell is positioned to absorb a first subset of incident light and reflect a first remainder of the incident light to the second solar cell through the solid optical element.

15. The photovoltaic system of claim 14, wherein the incident light comprises a plurality of subsets of the light spectrum, and wherein concentrated light having a light spectrum exits from the output end of the optical concentrator element, the system further comprising:
a second solar cell for absorbing a second subset of the light spectrum from the first remainder of the light and for reflecting a second remainder of the light;
a third solar cell for absorbing a third subset of the light spectrum from the second remainder of the light and for reflecting a third remainder of the light; and
a fourth solar cell for absorbing a fourth subset of the light spectrum from the third remainder of the light and for reflecting a fourth remainder of the light;
wherein the optical module comprises a solid parallelepiped structure that refracts the concentrated light.
